(19) United States
(12) Patent Application Publication
(10) Pub. No.: US 2023/0176196 A1
(43) Pub. Date: Jun. 8, 2023

(54) SUBMOUNT FOR A TRANSMITTER OF AN OPTICAL SENSING SYSTEM INCLUDING A PAIR OF CO-PACKAGED LASER BARS

(71) Applicant: BEIJING VOYAGER TECHNOLOGY CO., LTD., Beijing (CN)

(72) Inventors: Yue Lu, Los Gatos, CA (US); Anan Pan, Fremont, CA (US); Youmin Wang, Berkeley, CA (US)

(73) Assignee: BEIJING VOYAGER TECHNOLOGY CO., LTD., Beijing (CN)

(21) Appl. No.: 17/545,741

(22) Filed: Dec. 8, 2021

(51) Int. Cl. G01S 7/481; H01S 5/40; H01S 5/0238; H01S 5/00; H01S 5/0234

(52) U.S. Cl. CPC G01S 7/4815; G01S 7/4817; H01S 5/0071; H01S 5/0234; H01S 5/0238; H01S 5/4025

(57) ABSTRACT

Embodiments of the disclosure provide for a submount for a transmitter of an optical sensing system. The submount may include a substrate. The submount may also include a set of alignment fiducials formed using semiconductor lithography and coupled to the substrate. Still further, the submount may include at least one laser bar coupled to the substrate based on the set of alignment fiducials.

### TECHNICAL FIELD

The present disclosure relates to a submount for a transmitter of an optical sensing system that includes co-packaged off-the-shelf (OTS) laser bars aligned with semiconductor-level precision on a ceramic substrate.

### BACKGROUND

Optical sensing systems, e.g., such as LiDAR systems, have been widely used in advanced navigation technologies, such as to aid autonomous driving or to generate high-definition maps. For example, a typical LiDAR system measures the distance to a target by illuminating the target with pulsed laser light beams that are steered towards an object in the far field using a scanning mirror, and then measuring the reflected pulses with a sensor. Differences in laser light return times, wavelengths, and/or phases (also referred to as “time-of-flight (ToF) measurements”) can then be used to construct digital three-dimensional (3D) representations of the target. Because using a narrow laser beam as the incident light can map physical features with very high resolution, a LiDAR system is particularly suitable for applications such as sensing in autonomous driving and high-definition map surveys.

To scan the narrow laser beam across a broad field-of-view (FOV) in two-dimensions (2D), conventional systems mount two separate one-axis scanning mirrors on separate actuators, which drive the scanning mirrors to rotate around their respective axes to scan the two dimensions, respectively. Rotation about one axis provides a fast sweep of the surrounding environment in one dimension and the other axis provides a slow sweeps in an orthogonal dimension. Using these sweeps, a digital 3D image (e.g., 3D point cloud) of the far-field can be constructed. The slow axis (or horizontal-axis) is typically implemented using mechanical actuator (e.g., a galvanometer) and the fast axis (or vertical-axis) can be implemented by a mechanical or solid-state actuator. Thus, the galvanometer may be configured to drive the scanning mirror to rotate about the horizontal-axis, and electrostatic drive combs drive the scanning mirror to rotate about the vertical-axis, for example.

Due to laser beam spreading, a high-resolution 3D point cloud may not be resolved without sub-pixelization. One way to achieve a high-resolution or “camera-like” LiDAR system, is with the use of a specific scanning pattern, laser array, and a detector array. For example, to achieve a resolution of 0.025 ° in both scanning directions, the vertical-axis scanner may operate at a scanning frequency of 1.7 kHz. With the horizontal-axis scanner operating at a scanning frequency of 10 Hz and a scanning angle of 60 °, the vertical-axis scanner needs to scan horizontally at a step of 0.4 ° per period. To accommodate these settings, an edge-emitting laser with non-uniformly spaced laser channels could be used. For example, eight channels of lasers need to be fired sequentially, and eventually incident on eight detector arrays. However, no such edge-emitting lasers are available off-the-shelf (OTS) and having one custom designed comes at great expense. Moreover, the length of a custom designed edge-emitting laser may be unsuitable for use in a LiDAR system.

Thus, there exists a need for an edge-emitting laser with a non-uniform distribution of laser channels that can be realized without the expense or size that comes with custom designing an edge-emitting laser.

### SUMMARY

Embodiments of the disclosure provide for a submount for a transmitter of an optical sensing system. The submount may include a substrate. The submount may also include a set of alignment fiducials formed using semiconductor lithography and coupled to the substrate. Still further, the submount may include at least one laser bar coupled to the substrate based on the set of alignment fiducials.

Embodiments of the disclosure also provide for a transmitter_of an optical sensing system. The transmitter may include a submount. The submount may include a substrate. The submount may also include a set of alignment fiducials formed using semiconductor lithography and coupled to the substrate. Still further, the submount may include at least one laser bar coupled to the substrate based on the set of alignment fiducials. The transmitter may also include a scanner. The scanner may be configured to steer a light beam emitted by the at least one laser bar towards an object.

Embodiments of the disclosure further provide for method of fabricating a transmitter submount for an optical sensing system. The method may include forming a substrate. The method may also include forming a set of alignment fiducials using semiconductor lithography. The method may further include coupling the set of alignment fiducials to the substrate. Still further, the method may include coupling at least one laser bar to the substrate based on the set of alignment fiducials.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a block diagram of an exemplary LiDAR system, according to embodiments of the disclosure.

FIG. 2A illustrates a schematic view of co-packaged laser bars of a light source, according to embodiments of the disclosure.

FIG. 2B illustrates a scanning pattern that may be realized using the co-packaged laser bars of FIG. 2A, according to embodiments of the disclosure.

FIG. 2C illustrates a schematic diagram that depicts the non-uniform distribution of laser channels and the corresponding detector array, according to embodiments of the disclosure.

FIG. 2D illustrates a schematic view of alignment fiducials coupled to a substrate of a laser submount, according to embodiments of the disclosure.

FIG. 2E illustrates a laser submount with co-packaged laser bars aligned using the alignment fiducials coupled to the substrate as shown in FIG. 2D, according to embodiments of the disclosure.

FIG. 3 illustrates a flow chart of an exemplary method for fabricating the laser submount of FIG. 2E, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

LiDAR is an optical sensing technology that enables autonomous vehicles to “see” the surrounding world, creating a virtual model of the environment to facilitate decision-making and navigation. An optical sensor (e.g., LiDAR transmitter and receiver) creates a 3D map of the surrounding environment using laser beams and time-of-flight (ToF) distance measurements. ToF, which is one of LiDAR’s operational principles, provides distance information by measuring the travel time of a collimated laser beam to reflect off an object and return to the sensor. Reflected light signals are measured and processed at the vehicle to detect, identify, and decide how to interact with or avoid objects.

As mentioned above in the BACKGROUND section, there is currently no easy and inexpensive way to produce a laser emitter with non-uniformly distributed laser channels. The high-resolution specifications mentioned above in the BACKGROUND section can be achieved using an edge-emitting laser with adjacent laser channels spaced 400 µm apart, except for the middle two laser channels, which are spaced 600 µm apart. The difference in spacing is adopted to enable the region in the 3D point cloud scanned between channel 4 and channel 5 to include high-resolution features. However, edge-emitting lasers with a non-uniform distribution of laser channels are not available OTS, and to custom design such a laser emitter would be both expensive and challenging due to the length (>3 mm) of the final semiconductor chip.

Ideally, such a laser emitter could be fabricated by co-packaging a pair of OTS laser bars onto a substrate such that the non-uniform spacing associated with the center laser channels is achieved. However, even a small misalignment of one of the laser bars in either transverse direction may significantly impact system precision to levels unacceptable for autonomous navigation. This is because a transverse misalignment on the substrate equates to an error in the direction the laser beams are steered towards the far-field.

One way to achieve a high-level of alignment precision is through semiconductor lithography. However, due to the heat generated by edge-emitting lasers, the substrate to which the laser bars are co-packaged cannot be a semiconductor or conductor, while still maintaining thermal safety limits. Instead, the substrate in such a system needs to be ceramic, which cannot be etched using semiconductor lithography.

To overcome these challenges, the present disclosure provides a co-packaging technique that enables relatively inexpensive OTS laser bars to be co-packaged onto a ceramic substrate with a high-degree of alignment accuracy. The exemplary co-packaging technique may include, for example, 1) forming a set of alignment fiducials from a semiconductor wafer using semiconductor lithography, 2) transferring and coupling the set of alignment fiducials to a ceramic substrate, and 3) coupling a pair of laser bars to the ceramic substrate based on the set of alignment fiducials. Thus, the co-packaging technique of the present disclosure can enable OTS laser bars to be co-packaged onto a ceramic substrate with the level of accuracy needed for the high-resolution LiDAR systems.

Some exemplary embodiments are described below with reference to a receiver used in LiDAR system(s), but the application of the emitter array disclosed by the present disclosure is not limited to the LiDAR system. Rather, one of ordinary skill would understand that the following description, embodiments, and techniques may apply to any type of optical sensing system (e.g., biomedical imaging, 3D scanning, tracking and targeting, free-space optical communications (FSOC), and telecommunications, just to name a few) known in the art without departing from the scope of the present disclosure.

Moreover, some exemplary embodiments are described below in connection to co-packaged laser bars that each respectively include four laser emitters for use in a system that operates at a vertical-axis scanning frequency of 1.7 kHz. However, the exemplary co-packaging technique is not limited to two laser bars, each with four laser emitters. Rather, the number of laser bars and the number of laser emitters per laser bar may be different depending on the vertical-axis scanning frequency used and the intended degree of resolution. For example, in a system that uses 3.4 kHz as the vertical-axis scanning frequency, two laser bars, each respectively including two laser emitters, may be co-packaged onto a ceramic substrate without departing from the scope of the present disclosure. The numbers of laser emitters in the laser bars do not necessarily have to be the same either. Also, depending on the number of laser bars and/or laser emitters per laser bar, the non-uniform spacing between the laser emitters may be different that those dimensions described below in connection with a two laser bar/four laser emitter per laser bar system.

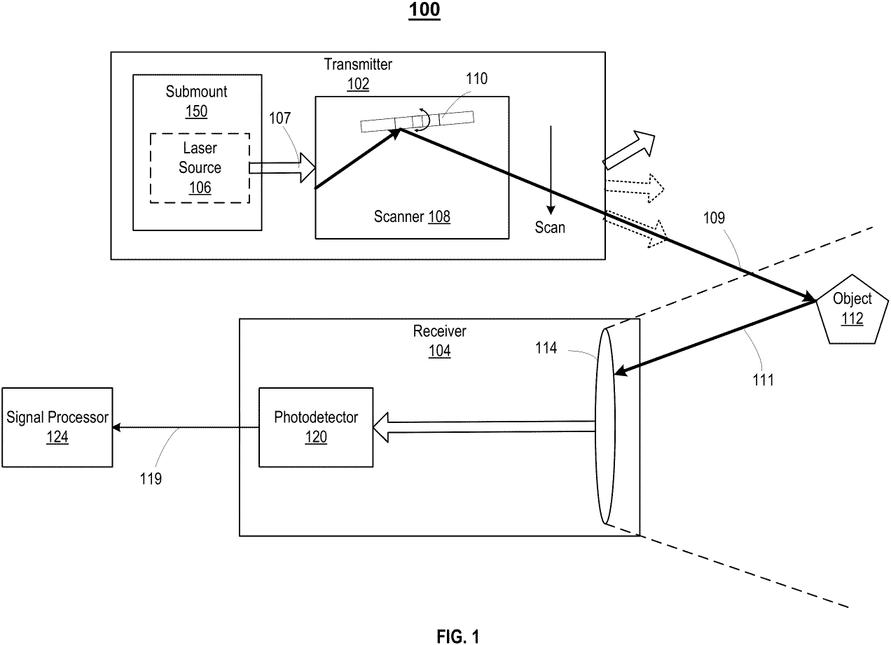

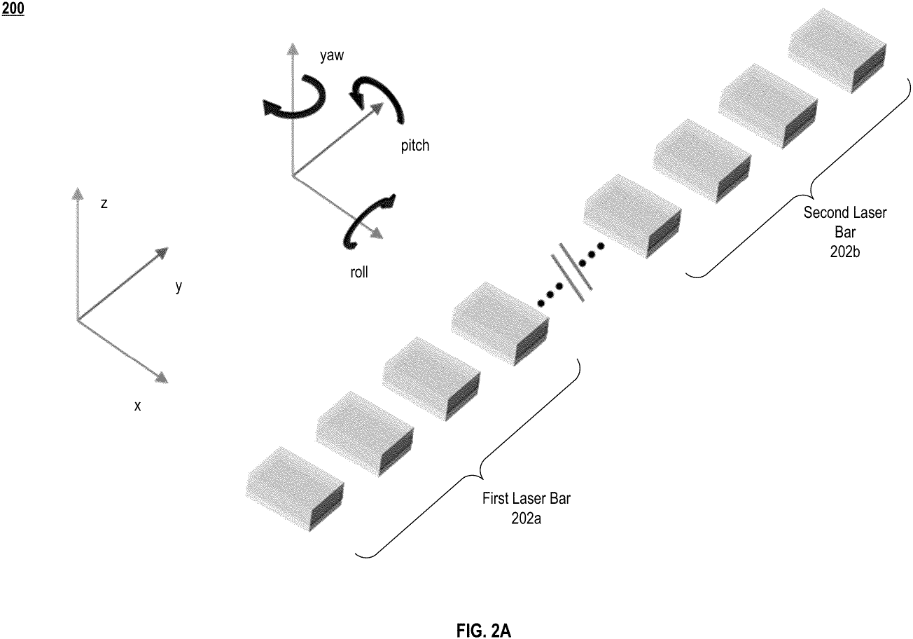

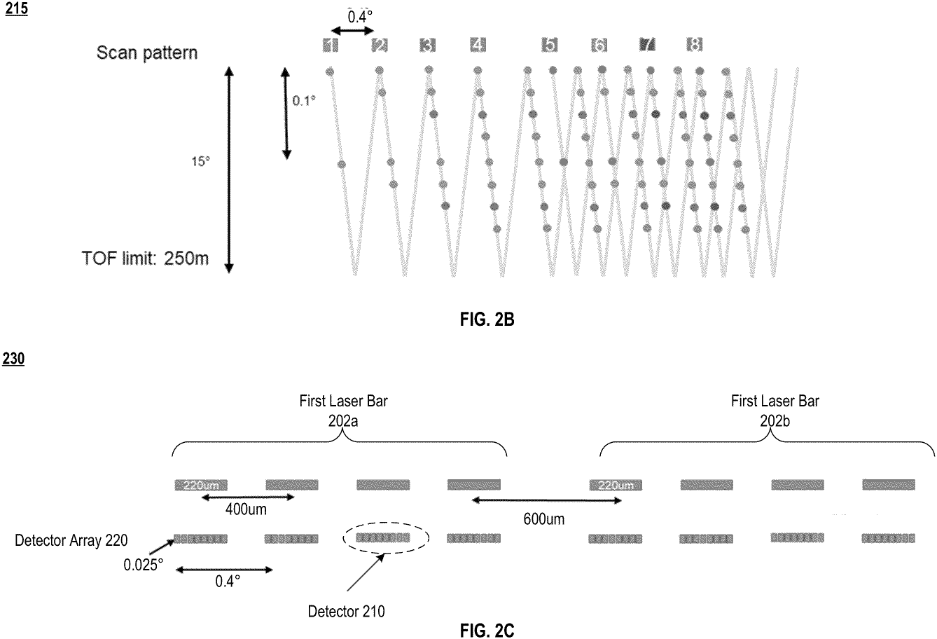

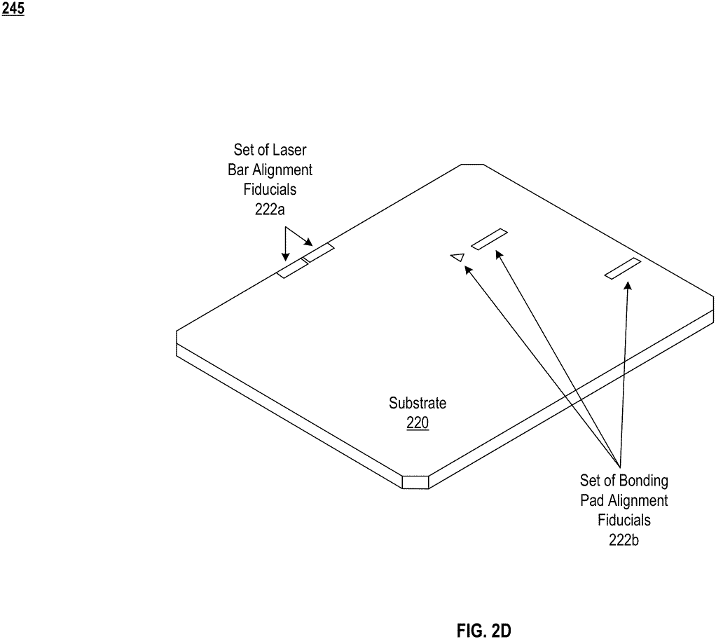

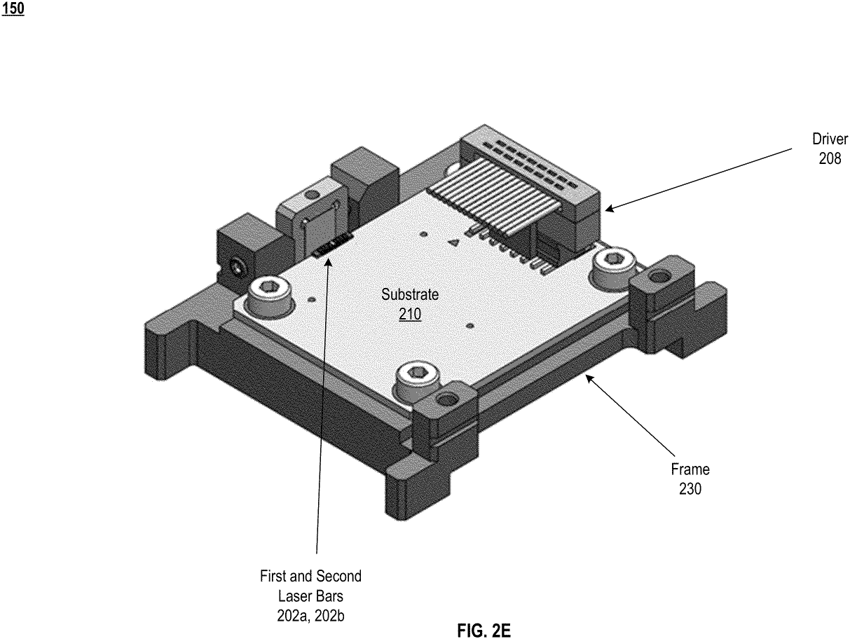

FIG. 1 illustrates a block diagram of an exemplary LiDAR system 100, according to embodiments of the disclosure. LiDAR system 100 may include a transmitter 102 and a receiver 104. Transmitter 102 may emit laser beams along multiple directions when performing a high-resolution scanning procedure. The laser beams may be generated by a laser source 106 that is part of a submount 150. Submount 150 may include a substrate (see FIGS. 2D and 2E) onto which a pair of laser bars (see FIGS. 2A, 2C, and 2E) and a driver (see FIG. 2E) are coupled. The pair of laser bars may be coupled to the substrate using the exemplary co-packaging technique described herein. As mentioned above, the exemplary co-packaging technique may include, for example, 1) forming a set of alignment fiducials using semiconductor lithography, 2) coupling the set of alignment fiducials to a ceramic substrate, and 3) coupling a pair of laser bars to the ceramic substrate based on the set of alignment fiducials. A driver may also be coupled to the substrate using the exemplary co-packaging technique.

Transmitter 102 can sequentially emit a stream of pulsed laser beams in different directions within a scan range (e.g., a range of scanning angles in angular degrees), as illustrated in FIG. 1. Laser source 106 (e.g., co-packaged laser bars) may be configured to provide a laser beam 107 (also referred to as “native laser beam”) to scanner 108. For example, the driver of submount 150 may drive each of the laser emitters to emit a pulsed laser beam in sequence. In some embodiments of the present disclosure, laser source 106 may generate a pulsed laser beam in the UV, visible, or near infrared wavelength range. Laser beam 107 may diverge in the space between the laser source 106 and the scanner 108. Thus, although not illustrated, transmitter 102 may further include a collimating lens located between laser source 106 and scanner 108 and configured to collimate divergent laser beam 107 before it impinges on scanner 108.

In some embodiments of the present disclosure, laser source 106 may include a pair of laser bars, which are edge-emitting semiconductor lasers, and aligned along an edge of a ceramic substrate of submount 150. Each laser bar may include a plurality of laser emitters equally spaced apart. For example, adjacent laser emitters of a single laser bar may be separated by a first distance (e.g., 100 µm, 200 µm, 400 µm, etc.). However, the pair of laser bars may be spaced apart on the substrate such that adjacent laser emitters respectively located in the two laser bars (e.g., the center two laser channels) are separated by a second distance (e.g., 200 µm, 300 µm, 600 µm, etc.), which is greater than the first distance. In one exemplary embodiment, laser channels 1 and 2 may be separated by 400 µm, laser channels 2 and 3 may be separated by 400 µm, laser channels 3 and 4 may be separated by 400 µm, laser channels 4 and 5 may be separated by 600 µm, laser channels 5 and 6 may be separated by 400 µm, and laser channels 7 and 8 may be separated by 400 µm. By increasing the distance between the center two laser channels, the high-resolution scanning procedure of the present disclosure (see FIG. 2B) can capture high-definition features in the region between the two center laser channels that would otherwise be missed if the center two laser channels were separated by the same distance as the other laser emitters.

Each of the laser emitters may be formed as, e.g., a pulsed laser diode (PLD), a vertical-cavity surface-emitting laser (VCSEL), a fiber laser, etc. For example, a PLD may be a semiconductor device similar to a light-emitting diode (LED) in which the laser beam is created at the diode’s junction. In some embodiments of the present disclosure, a PLD includes a PIN diode in which the active region is in the intrinsic (I) region, and the carriers (electrons and holes) are pumped into the active region from the N and P regions, respectively. Depending on the semiconductor materials, the wavelength of incident laser beam 107 provided by a PLD may be greater than 700 nm, such as 760 nm, 785 nm, 808 nm, 848 nm, 905 nm, 940 nm, 980 nm, 1064 nm, 1083 nm, 1310 nm, 1370 nm, 1480 nm, 1512 nm, 1550 nm, 1625 nm, 1654 nm, 1877 nm, 1940 nm, 2000 nm, etc. It is understood that any suitable edge-emitting laser bar may be used as laser source 106 for emitting laser beam 107.

Scanner 108 may be configured to steer a laser beam 109 towards an object 112 (e.g., stationary objects, moving objects, people, animals, trees, fallen branches, debris, metallic objects, non-metallic objects, rocks, rain, chemical compounds, aerosols, clouds and even single molecules, just to name a few) in a direction within a range of scanning angles. In some embodiments consistent with the present disclosure, scanner 108 may include a micromachined mirror assembly, e.g., such as scanning mirror 110. Scanning mirror 110 may be a microelectricalmechanical (MEMS) mirror. Scanning mirror 110 may be configured to resonate during the scanning procedure. Although not shown in FIG. 1, the micromachined mirror assembly of scanner 108 may also include various other elements. For example, these other elements may include, without limitation, a MEMS actuator, actuator anchor(s), a plurality of interconnects, scanning mirror anchor(s), just to name a few.

In some embodiments, receiver 104 may be configured to detect a returned laser beam 111 returned from object 112. Returned laser beam 111 may be returned from object 112 and have the same wavelength as laser beam 109. Returned laser beam 111 may be in a different direction from laser beam 109. Receiver 104 can collect laser beams returned from object 112 and output electrical signals reflecting the intensity of the returned laser beams. Upon contact, laser beam 109 can be reflected by object 112 via backscattering, e.g., such as Raman scattering and/or fluorescence.

As illustrated in FIG. 1, receiver 104 may receive the returned laser beam 111. During the scanning procedure, returned laser beam 111 may be collected by lens 114 as laser beam 121. Photodetector array 120 may convert the laser beam 121 (e.g., returned laser beam 111) collected by lens 114 into an electrical signal 119 (e.g., a current or a voltage signal). Electrical signal 119 may be generated when photons are absorbed in a photodiode included in photodetector array 120. In some embodiments of the present disclosure, photodetector array 120 may include a PIN detector, a PIN detector array, an avalanche photodiode (APD) detector, a APD detector array, a single photon avalanche diode (SPAD) detector, a SPAD detector array, a silicon photo multiplier (SiPM/MPCC) detector, a SiP/MPCC detector array, or the like.

LiDAR system 100 may also include one or more signal processor 124. Signal processor 124 may receive electrical signal 119 generated by photodetector array 120. Signal processor 124 may process electrical signal 119 to determine, for example, distance information carried by electrical signal 119. Signal processor 124 may construct a point cloud based on the processed information. The point cloud may include a frame, which is an image of the far-field at a particular point in time. In this context, a frame is the data/image captured of the far field environment within the 2D FOV (horizontal FOV and vertical FOV). Signal processor 124 may include a microprocessor, a microcontroller, a central processing unit (CPU), a graphical processing unit (GPU), a digital signal processor (DSP), or other suitable data processing devices.

FIG. 2A illustrates a detail view 200 of a pair of co-packaged laser bars of submount 150 of FIG. 1, according to embodiments of the disclosure. FIG. 2B illustrates a graphical representation 215 of an exemplary scanning procedure that may be performed using the pair of laser bars of FIG. 2A, according to embodiments of the disclosure. FIG. 2C illustrates a schematic view 230 of laser emitters and the corresponding detector arrays, according to embodiments of the disclosure. FIG. 2D illustrates a schematic diagram 245 of a substrate that includes a set of alignment fiducials coupled thereto for use in aligning a pair of laser bars and a driver, according to embodiments of the disclosure. FIG. 2E illustrates a detailed view of submount 150 that includes laser bars coupled to the substrate of FIG. 2D based on the exemplary co-packaging technique, according to embodiments of the disclosure. FIGS. 2A-2E will be described together.

The exemplary scanning procedure depicted in FIG. 2B may be associated with a scanning frequency of 1.7 kHz in the vertical direction and 10 Hz in the horizontal direction, for example. Using a scanning frequency of 1.7 kHz in the vertical direction may have several benefits over using a higher scanning frequency, such as 3.4 kHz. This is because using a lower scanning frequency reduces ambient light collection at the detector 210. of FIG. 2C.

Furthermore, the scanning frequency in the vertical direction may determine the number of vertical lines scanned per frame. Hence, the number of laser channels associated with a vertical-axis scanning frequency of 1.7 kHz is greater than the number of laser channel associated with 3.4 kHz. For example, eight laser channels (shown in FIGS. 2A-2C and 2E) may be used for a scanning procedure with a vertical-axis scanning frequency of 1.7 kHz. On the other hand, four laser channels (not shown) may be used for a scanning procedure with a vertical-axis scanning frequency of 3.4 kHz.

Referring to FIG. 2C, due to beam spreading, each detector 210 of detector array 220 may include eight detectors, which enables high-resolution features of objects to be captured in the 3D point cloud. Moreover, the ToF of the laser beam is about 1 ms; during this ToF, the scanner 108 is also moving (e.g., resonating). So, when the returned laser beam reaches scanner 108, scanning mirror 110 has shifted position. To accommodate this shift, detector 210 has a relatively large FOV in the vertical axis (e.g., 0.4 ° FOV), which adds to the ambient light collection. Ambient light collection may generate signal noise and reduce detection range, as well as precision. Thus, for also this reason, a vertical-axis scanning frequency of 1.7 kHz may be desirable.

To accommodate a vertical-axis scanning frequency of 1.7 kHz, while avoiding the manufacturing expense and chip size of custom designed laser bars, the present disclosure provides a co-packaging technique to form the side-by-side laser bars with additional spacing between the center laser channels (e.g., channels 4 and 5), as shown in FIGS. 2A, 2C, and 2E.

However, as mentioned above, even a small misalignment of the first laser bar 202a and/or the second laser bar 202b along either the x-axis (first transverse direction) or the y-axis (second transverse direction) of the substrate can cause significant errors that reduce overall accuracy to levels unacceptable for autonomous navigation. This is because any transverse misalignment of the laser bars generates the same amount of angular misalignment in the 3D point cloud. For example, a 1 milliradian (mrad) directional error in either yaw, pitch, or roll would cause the same amount of directional error. The maximum amount of misalignment that can be tolerated in either transverse direction may be different depending on the system and number of laser channels used. By way of example, a transverse misalignment of +/- 5 µm may cause the following angular misalignments in the final point cloud: 1) 0.5 mrad in the x- direction, 2) 0.1 mrad in the y- direction, and 3) 0.5 mrad in the z-direction. Angular misalignments greater than those listed above may be unacceptable from a precision and safety standpoint. Thus, in some embodiments, the maximum transverse misalignment may be +/- 5 µm, which may also be referred to as the “misalignment tolerance threshold.”

Semiconductor lithography can achieve this level of alignment precision by etching (into a semiconductor wafer) alignment fiducials, which can then be used for placement of first and second laser bars 202a, 202b. However, because first and second laser bars 202a, 202b generate a certain amount of heat during operation, it is beneficial for substrate 220 to include a ceramic rather than semiconductor material. Using a ceramic material for substrate 220 may enable thermal safety limits within transmitter 102 to be maintained, for example. However, ceramic materials cannot be etched using semiconductor-lithography techniques.

Thus, according to the exemplary co-packaging technique of the present disclosure, a set of alignment fiducials may be etched on a semiconductor wafer using semiconductor-lithography, and then transferred and coupled to a ceramic substrate, e.g., substrate 220. The precise alignment of the set of alignment fiducials may then be used for placement of the pair of laser bars.

For example, referring to FIG. 2D, the set of laser bar alignment fiducials 222a may be formed from a semiconductor wafer using lithography. Once formed, the set of laser bar alignment fiducials 22a may be transferred and coupled to substrate 220, which may be formed from a ceramic material. A set of bonding pad alignment fiducials 222b may also be formed during the same lithography process and transferred and couped to substrate 220. Then, using flip chip bonding (or any other suitable bonding technique), first and second laser bars 202a, 202b may be coupled to substrate 220 at the set of laser bar alignment fiducials 222a. A driver 208 may be bonded at the set of bonding pad alignment fiducials 222b. In some embodiments, driver 208 may be coupled to substrate 220 during the same flip chip bonding process as the first and second laser bars 202a, 202b. However, in some other embodiments, driver 208 may be coupled to substrate 220 using a separate bonding technique. Referring to FIG. 2E, substrate 220, the set of laser bar alignment fiducials 222a, the set of bonding pad alignment fiducials 222b, first and second laser bars 202a, 202b, and driver 208 (as well as other components) may be coupled to a frame 230, which forms submount 150 of FIG. 1.

Thus, using the co-packaging technique described above in connection with FIGS. 2A-2E a pair of OTS laser bars can be co-packaged such that there is a non-uniform distribution between adjacent laser emitters and a high-degree of alignment precision. The co-packaging technique reduces cost as compared to a custom designed laser bar with a non-uniform distribution of laser emitters. The non-uniform distribution enables the generation of a 3D point cloud with high-resolution features captured in every region of the far-field. Moreover, the co-packaged laser bars of the present disclosure may be used in a LiDAR system that employs a 1.7 kHz vertical-axis scanning frequency to reduce ambient light collection at the detector.

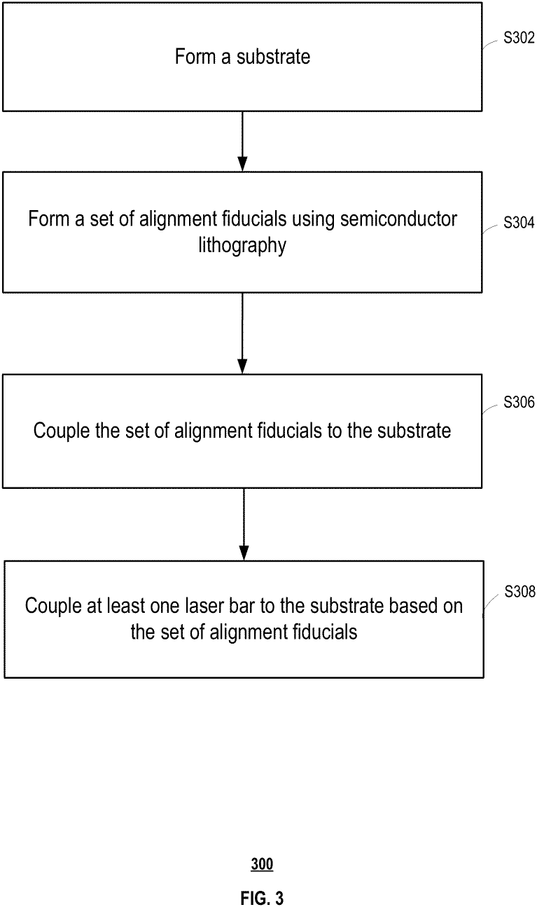

FIG. 3 illustrates a flowchart of an exemplary method 300 of fabricating a transmitter submount for an optical sensing system, according to embodiments of the disclosure. Method 300 may include steps S302-S308 as described below. It is to be appreciated that some of the steps may be optional, and some of the steps may be performed simultaneously, or in a different order than shown in FIG. 3.

Referring to FIG. 3, at S302, a substrate may be formed. For example, referring to FIG. 2E, substrate 220 may be formed of a ceramic material. The ceramic material may include, e.g., aluminum oxide or aluminum nitride.

At S304, a set of alignment fiducials may be formed using semiconductor-lithography. For example, referring to FIG. 2D, the set of laser bar alignment fiducials 222a may be formed from a semiconductor wafer using semiconductor lithography. The set of bonding pad alignment fiducials 222b may also be formed using the same or a different semiconductor lithography process as that used for the set of laser bar alignment fiducials 222a.

At S306, the set of alignment fiducials may be coupled to the substrate. For example, referring to FIG. 2D, the set of laser bar alignment fiducials 222a and/or the set of bonding pad alignment fiducials 222b may be coupled to substrate 220.

At S308, at least one laser bar may be coupled to the substate based on the set of alignment fiducials. For example, referring to FIG. 2E, first and second laser bars 202a, 202b may be coupled to substrate 220 at the set of laser bar alignment fiducials 222a. Using the set of laser bar alignment fiducials 222a generated using semiconductor-level precision, first and second laser bars 202a, 202b may be aligned with the level of accuracy needed for autonomous navigation.

It is intended that the specification and examples be considered as exemplary only, with a true scope being indicated by the following claims and their equivalents.

What is claimed is:

1. A submount for a transmitter of an optical sensing system, comprising:
a substrate;
a set of alignment fiducials formed using semiconductor lithography and coupled to the substrate; and
at least one laser bar coupled to the substrate based on the set of alignment fiducials.

2. The submount of claim 1, wherein the set of alignment fiducials comprise a set of laser bar alignment fiducials, and wherein the at least one laser bar is coupled to the substrate based on the set of laser bar alignment fiducials.

3. The submount of claim 2, wherein the set of alignment fiducials further comprises a set of bonding pad alignment fiducials, wherein the submount further comprises:
a driver coupled to the substrate based on the set of bonding pad alignment fiducials.

4. The submount of claim 1, wherein the substrate is formed of a ceramic material.

5. The submount of claim 4, wherein the ceramic material comprises aluminum oxide or aluminum nitride.

6. The submount of claim 1, wherein the at least one laser bar comprises two laser bars positioned side-by-side along an edge of the substrate based on the set of alignment fiducials.

7. The submount of claim 6, wherein the two laser bars are flip chip bonded to the substrate at the set of alignment fiducials.

8. The submount of claim 6, wherein:
the two laser bars are positioned along the edge of the substrate to within a misalignment tolerance threshold provided by the set of alignment fiducials, and
the misalignment tolerance threshold is associated with a first distance offset in a first transverse direction on a surface of the substrate and a second distance offset in a second transverse direction on the surface of the substrate.

9. The submount of claim 6, wherein each of the two laser bars comprises a set of laser emitters, wherein:
a first pair of adjacent laser emitters within one of the two laser bars are separated by a first distance, and
a second pair of adjacent laser emitters respectively located in the two laser bars positioned side-by-side are separated by a second distance greater than the first distance.

10. A transmitter of an optical sensing system, comprising:
a submount comprising:
a substrate;
a set of alignment fiducials formed using semiconductor lithography and coupled to the substrate; and
at least one laser bar coupled to the substrate based on the set of alignment fiducials; and
a scanner configured to steer a light beam emitted by the at least one laser bar towards an obj ect.

11. The transmitter of claim 10, wherein the set of alignment fiducials comprise a set of laser bar alignment fiducials, and wherein the at least one laser bar is coupled to the substrate based on the set of laser bar alignment fiducials.

12. The transmitter of claim 11, wherein the set of alignment fiducials further comprises a set of bonding pad alignment fiducials, wherein the submount further comprises:
a driver coupled to the substrate based on the set of bonding pad alignment fiducials.

13. The transmitter of claim 10, wherein the substrate is formed of aluminum oxide or aluminum nitride.

14. The transmitter of claim 10, wherein the at least one laser bar comprises two laser bars flip chip bonded along an edge of the substrate based on the set of alignment fiducials to within a misalignment tolerance threshold provided by the set of alignment fiducials.

15. The transmitter of claim 14, wherein each of the two laser bars comprises a set of laser emitters, wherein:
a first pair of adjacent laser emitters within one of the two laser bars are separated by a first distance, and
a second pair of adjacent laser emitters respectively located in the two laser bars positioned side-by-side are separated by a second distance greater than the first distance.

16. A method of fabricating a transmitter submount for an optical sensing system, comprising:
forming a substrate;
forming a set of alignment fiducials using semiconductor lithography;
coupling the set of alignment fiducials to the substrate; and
coupling at least one laser bar to the substrate based on the set of alignment fiducials.

17. The method of claim 16, wherein the set of alignment fiducials comprise a set of laser bar alignment fiducials, and wherein the at least one laser bar is coupled to the substrate based on the set of laser bar alignment fiducials.

18. The method of claim 17, wherein the set of alignment fiducials further comprises a set of bonding pad alignment fiducials, wherein the method further comprises:
coupling a driver to the substrate based on the set of bonding pad alignment fiducials.

19. The method of claim 16, wherein coupling the at least one laser bar to the substrate comprises:
flip chip bonding two laser bars side-by-side along an edge of the substrate to within a misalignment tolerance threshold provided by the set of alignment fiducials,
wherein the misalignment tolerance threshold is associated with a first distance offset in a first transverse direction on a surface of the substrate and a second distance offset in a second transverse direction on the surface of the substrate.

20. The method of claim 19, wherein each of the two laser bars comprises a set of laser emitters, wherein:
a first pair of adjacent laser emitters within one of the two laser bars are separated by a first distance, and
a second pair of adjacent laser emitters respectively located in the two laser bars flip chip bonded side-by-side are separated by a second distance greater than the first distance.
